(19) United States
(12) Patent Application Publication
(10) Pub. No.: US 2026/0260622 A1
(43) Pub. Date: Sep. 3, 2026

(54) DISPLAY DEVICE AND TIMING CONTROLLER

(71) Applicant: LG Display Co., Ltd., Seoul (KR)

(72) Inventor: Intae KO, Paju-si (KR)

(21) Appl. No.: 19/551,516

(22) Filed: Feb. 26, 2026

(30) Foreign Application Priority Data
Feb. 28, 2025 (KR) 10-2025-0026302

(51) Int. Cl. G09G 3/3266

(52) U.S. Cl. CPC G09G 3/3266; G09G 2300/0819; G09G 2310/08; G09G 2330/027; G09G 2380/10

(57) ABSTRACT

A display device includes a general area, an optical area that is transmissive to light, and a boundary area disposed between the general area and the optical area; a unit pixel comprising at least two pixels that are disposed in the boundary area, the at least two pixels that emits light by receiving a gate signal through a gate driving circuit in the display panel; and a timing controller that controls the gate driving circuit. At least some of the at least two pixels included in the unit pixel emit light in a high luminance state, and the remaining pixels emit light in a low luminance state, and the high luminance state or the low luminance state of the at least two pixels sequentially changes within the unit pixel according to a value of a counting signal of the timing controller.

### CROSS REFERENCE TO RELATED APPLICATION

This application claims priority from and the benefit of Korean Patent Application No. 10-2025-0026302, filed on February 28, 2025, which is hereby incorporated by reference for all purposes as if fully set forth herein.

### BACKGROUND

### Field

Embodiments of the invention relate generally to a display device and a timing controller.

### DISCUSSION OF THE BACKGROUND

As the information-oriented society has developed, the demand for display devices for displaying images has increased in various forms, and recently, various display devices such as liquid crystal display devices and organic light-emitting display devices have been utilized.

In addition, a display device may be configured to provide a sensing function that operates in response to ambient light. For this purpose, the display device may include various electronic devices (optical electronic devices), such as a detection sensor or an image sensor (camera).

Because the electronic device needs to receive light from the front of the display device, a transmissive area having a cathode hole is formed in a cathode electrode of an area in which the electronic device is disposed.

Because the transmissive area replaces a light-emitting area in which a light-emitting device is conventionally disposed, a difference in light-emitting characteristics may occur between the area where the electronic device is disposed and the area where it is not, and as a result, a boundary line may be visible between the two areas.

The above information disclosed in this Background section is only for understanding of the background of the inventive concepts, and, therefore, it may contain information that does not constitute prior art.

### SUMMARY

Embodiments of the present disclosure provide a display device and a timing controller that may obviate the need for a notch or a hole to expose an optical electronic device, thereby reducing the size of a bezel area and increasing the degree of freedom in design by eliminating design constraints.

Embodiments of the present disclosure provide a display device and a timing controller capable of preventing visibility of a boundary line between an optical area and a boundary area by driving pixels disposed in the boundary area to mimic the layout characteristics of pixels disposed in the optical area and the transmissive area, and by gradually setting the luminance to match that of pixels disposed in a general area as the distance from the optical area increases.

Embodiments of the present disclosure provide a display device and a timing controller capable of solving the problem of reduced lifespan of a specific pixel due to concentration of high luminance operation on the specific pixel by sequentially changing pixels within a unit pixel disposed in the boundary area based on a certain point in time.

Additional features of the inventive concepts will be set forth in the description which follows, and in part will be apparent from the description, or may be learned by practice of the inventive concepts.

According to embodiments of the present disclosure, a display device includes: a display panel including a general area, an optical area that is configured to transmit light, and a boundary area disposed between the general area and the optical area; a unit pixel including at least two pixels that are disposed in the boundary area and emit light by receiving a gate signal through a gate driving circuit in the display panel; and a timing controller configured to control the gate driving circuit, in which at least some of the at least two pixels included in the unit pixel emit light in a high luminance state, and the remaining pixels emit light in a low luminance state, and the high luminance state or the low luminance state of the at least two pixels may sequentially change within the unit pixel according to a value of a counting signal of the timing controller.

In case that power is applied to the display panel, a start signal may be supplied from the timing controller, and a value of the counting signal may be incremented each time the start signal is supplied to the timing controller.

The gate driving circuit may receive a gate start signal from the timing controller for each frame of an image displayed on the display panel, and the counting signal may correspond to a value that is incremented each time the gate start signal is supplied to the gate driving circuit.

Among the at least two pixels included in the unit pixel, one pixel may be configured to emit light in the high luminance state, and the remaining pixels, other than the pixel that emits light in the high luminance state, may emit light in the low luminance state.

The unit pixel may include N pixels, where N is a natural number equal to or greater than 2, a value of the counting signal may be sequentially incremented from a value indicating a first state to a value indicating an N-th state under control of the timing controller, and after the value indicating the N-th state, the value may be again incremented starting from the value indicating the first state, in case that the counting signal has a value indicating the first state, a first pixel in the unit pixel may emit light in the high luminance state, and the remaining pixels may emit light in the low luminance state, and in case that the counting signal has a value indicating the N-th state, an N-th pixel in the unit pixel may emit light in the high luminance state, and the remaining pixels may emit light in the low luminance state.

In the boundary area, luminance of the pixels that emits light in the high luminance state may gradually decrease as a distance from the optical area increases, and luminance of the pixels that emits light in the low luminance state gradually may increase as the distance from the optical area increases.

The optical area may include a transmissive area that is configured to transmit light, and the transmissive area and the pixels may not be vertically overlapped in the display panel, and the number of pixels per unit area in the optical area may be less than in the general area and the boundary area.

An optical electronic device may be disposed in the optical area, and the optical electronic device may be configured to perform a predefined operation using light transmitted through the transmissive area.

The display panel may be disposed in a front cluster of an interior of a vehicle.

According to another embodiment of the present disclosure, a timing controller is configured to control a plurality of pixels disposed in a display panel and emitting light by receiving gate signals through a gate driving circuit. The timing controller may be configured to control a unit pixel including at least two pixels disposed in the display panel. At least some of the at least two pixels included in the unit pixel may be configured to emit light in a high luminance state, and the remaining pixels is configured to emit light in a low luminance state. The high luminance state or the low luminance state of the at least two pixels sequentially may change within the unit pixel according to a value of a counting signal of the timing controller.

In case that power is applied to the display panel, a start signal may be supplied to the timing controller, and a value of the counting signal may be incremented each time the start signal is supplied to the timing controller.

The gate driving circuit may be configured to receive a gate start signal from the timing controller for each frame of an image displayed on the display panel, and a value of the counting signal may be incremented each time the gate start signal is supplied to the gate driving circuit.

The unit pixel may include N pixels, where N is a natural number equal to or greater than 2, a value of the counting signal may be sequentially incremented from a value indicating a first state to a value indicating an N-th state under control of the timing controller, and after the value indicating the N-th state, the value may again be incremented starting from the value indicating the first state, in case that the counting signal has a value indicating the first state, a first pixel in the unit pixel may emit light in the high luminance state, and the remaining pixels may emit light in the low luminance state, and in case that the counting signal has a value indicating the N-th state, an N-th pixel in the unit pixel may emit light in the high luminance state, and the remaining pixels may emit light in the low luminance state.

The timing controller may further include a memory in which the value of the counting signal is stored.

The luminance of pixels that emits light in the high luminance state at a first point of the display panel may gradually decrease as a distance from the first point increases, and the luminance of pixels that emits light in the low luminance state at the first point may gradually increase as a distance from the first point increases.

According to another embodiment of the present disclosure, a method of driving a display device includes: applying power to the display device; supplying power to a timing controller and generating, by the timing controller, a start signal; accumulating the generated start signal in a memory disposed in the timing controller; initializing a gate driving circuit by supplying an initialization signal from the timing controller to the gate driving circuit; displaying a black screen on the display panel after initialization of the gate driving circuit; repeatedly performing a blank stage and a display driving stage while the display device remains powered on; displaying an image on the display panel after the blank stage ends; determining whether a power-off signal is applied from the display device; and in response to determining that the power‑off signal is applied, turning off power and stopping driving of the display device.

The accumulating of the generated start signal may include incrementing a counting value stored in the memory each time the timing controller generates the start signal.

The initializing of the gate driving circuit may include discharging nodes of the gate driving circuit to an initial voltage level or setting the nodes to a predetermined reference voltage.

The displaying of the black screen may include supplying, by a data driving circuit, data voltages that minimize light emission of all sub‑pixels included in the display panel.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the inventive concepts.

FIG. 1 is a schematic view illustrating a display device according to an embodiment of the present disclosure.

FIG. 2 is a schematic view illustrating an example in which the display device according to an embodiment of the present disclosure is applied to a vehicle.

FIG. 3 is a schematic system configuration diagram of the display device according to an embodiment of the present disclosure.

FIG. 4 is a schematic view illustrating a display panel according to an embodiment of the present disclosure.

FIG. 5 is a schematic plan view showing an enlarged view of area A shown in FIG. 3.

FIG. 6 is a schematic view illustrating sub-pixels (SPs) disposed in a boundary area and an optical area, shown in area B of FIG. 5.

FIG. 7 is a schematic table showing a simulation result of expected pixel lifespans at different temperatures for pixels disposed in a general area, a boundary area, and an optical area.

FIG. 8, FIG. 9, FIG. 10 and FIG. 11 are schematic views illustrating a feature in which pixels disposed in a boundary area are sequentially driven, shown in area C of FIG. 5.

FIG. 12 and FIG. 13 are schematic flowcharts illustrating an operation of the display device for adjusting a timing of luminance change of pixels that emits light in a high luminance state.

### DETAILED DESCRIPTION

In the following description, for the purposes of explanation, numerous specific details are set forth in order to provide a thorough understanding of various embodiments or implementations of the invention. As used herein “embodiments” and “implementations” are interchangeable words that are non-limiting examples of devices or methods employing one or more of the inventive concepts disclosed herein. It is apparent, however, that various embodiments may be practiced without these specific details or with one or more equivalent arrangements. In other instances, well-known structures and devices are shown in block diagram form in order to avoid unnecessarily obscuring various embodiments. Further, various embodiments may be different, but do not have to be exclusive. For example, specific shapes, configurations, and characteristics of an embodiment may be used or implemented in another embodiment without departing from the inventive concepts.

Unless otherwise specified, the illustrated embodiments are to be understood as providing features of varying detail of some ways in which the inventive concepts may be implemented in practice. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the inventive concepts.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the D1-axis, the D2-axis, and the D3-axis are not limited to three axes of a rectangular coordinate system, such as the x, y, and z – axes, and may be interpreted in a broader sense. For example, the D1-axis, the D2-axis, and the D3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of idealized embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the inventive concepts. Further, the blocks, units, and/or modules of some embodiments may be physically combined into more complex blocks, units, and/or modules without departing from the scope of the inventive concepts.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and should not be interpreted in an idealized or overly formal sense, unless expressly so defined herein.

In addition, when any dimensions, relative sizes etc. are mentioned, it should be considered that numerical values for elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

Hereinafter, various embodiments of the present disclosure will be described in detail with reference to the accompanying drawings.

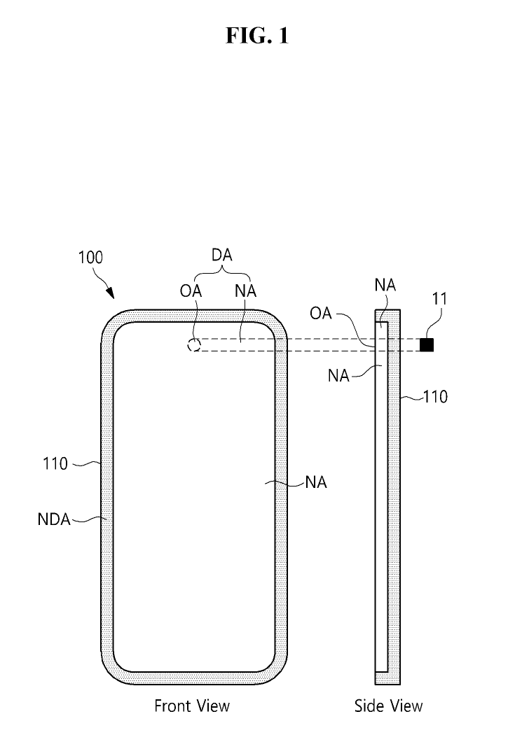

FIG. 1 is a view illustrating a display device 100 according to an embodiment of the present disclosure.

Referring to FIG. 1, the display device 100 according to an embodiment of the present disclosure may include a display panel 110 for displaying an image and an optical electronic device 11.

The display panel 110 may include a display area DA in which an image is displayed, and a non-display area NDA in which an image is not displayed.

A plurality of sub-pixels may be disposed in the display area DA, and various signal lines for driving the plurality of sub-pixels may be disposed.

The non-display area NDA may be an outer area of the display area DA. Various signal lines may be disposed in the non-display area NDA, and various driving circuits may be connected thereto. The non-display area NDA may be bent such that it is not visible from the front, or may be covered by a case (not shown). The non-display area NDA may also be referred to as a bezel or a bezel area.

Referring to FIG. 1, in the display device 100 according to an embodiment of the present disclosure, the optical electronic device 11 may be an electronic component located under (opposite to a viewing surface of) the display panel 110.

Light may enter through a front surface (viewing surface) of the display panel 110, pass through the display panel 110, and be transmitted to the optical electronic device 11 located under (on the opposite side of) the display panel 110.

The optical electronic device 11 may be a device that receives light transmitted through the display panel 110 and performs a predefined function according to the received light. For example, the optical electronic device 11 may include an imaging device such as a camera (image sensor).

Referring to FIG. 1, in the display panel 110 according to an embodiment of the present disclosure, the display area DA may include a general area NA and an optical area OA.

Referring to FIG. 1, the optical area OA may be an area that overlaps the optical electronic device 11.

According to the example in FIG. 1, the display area DA may include the general area NA and the optical area OA. At least a portion of the optical area OA may overlap the optical electronic device 11.

Although FIG. 1 illustrates an example in which the optical area OA has a circular shape, the shape of the optical area OA according to an embodiment of the present disclosure is not limited thereto.

For example, the optical area OA may have various shapes such as a circular shape, an elliptical shape, a rectangular shape, a hexagonal shape, or an octagonal shape. In the following description, for convenience of explanation, it is assumed that the optical area OA has a circular shape.

In another embodiment, two or more optical areas OA may be included (not shown in the drawings). In this case, an optical electronic device 11 may be disposed in each of the two or more optical areas OA.

In addition, the optical area OA may require both an image display structure and a light transmission structure. In particular, because the optical area OA is a part of the display area DA, sub-pixels for displaying an image must be disposed in the optical area OA. Also, a light transmission structure for transmitting light to the optical electronic device 11 must be formed in the optical area OA.

The optical electronic device 11 is a device that requires light reception but is located behind (under, opposite to the viewing surface of) the display panel 110, and thus receives light that has passed through the display panel 110.

The optical electronic device 11 is not exposed on the front surface (viewing surface) of the display panel 110. Accordingly, when a user views the front of the display device 100, the optical electronic device 11 is not visible to the user.

For example, the optical electronic device 11 may be a camera or an infrared detection sensor. The type of the optical electronic device 11 is not limited thereto.

Hereinafter, for convenience of description, an example is given in which the optical electronic device 11 is a camera. The camera may be a camera lens or an image sensor.

When the optical electronic device 11 is a camera, the camera may be a front camera that captures an image in the direction of the front surface of the display panel 110, although it is located behind (under) the display panel 110. Accordingly, a user may perform image capturing through the camera, which is not visible on the viewing surface, while viewing the viewing surface of the display panel 110.

The general area NA and the optical area OA included in the display area DA are both areas capable of displaying an image. However, the general area NA is an area in which a light transmission structure does not need to be formed, and the optical area OA is an area in which a light transmission structure must be formed.

Accordingly, the optical area OA must have a light transmittance above a certain level, and the general area NA may have no light transmittance or may have a low light transmittance below a certain level.

For example, the optical area OA and the general area NA may differ from each other in resolution, sub-pixel arrangement structure, number of sub-pixels per unit area, electrode structure, line structure, electrode arrangement structure, or line arrangement structure.

For example, the number of sub-pixels per unit area in the optical area OA may be smaller than the number of sub-pixels per unit area in the general area NA. In particular, the resolution of the optical area OA may be lower than the resolution of the general area NA. The number of sub-pixels per unit area refers to a unit used to measure resolution and may also be referred to as PPI (Pixels Per Inch), which indicates the number of pixels within one inch.

For example, the number of sub-pixels per unit area in the optical area OA may be smaller than the number of sub-pixels per unit area in the general area NA.

Accordingly, in the case of the display device 100 according to an embodiment of the present disclosure, because a notch or hole for the optical electronic device 11 is not formed in the display panel 110, reduction in the area of the display area DA does not occur.

Accordingly, because a notch or hole for exposing the optical electronic device 11 is not formed in the display panel 110, the size of a bezel area may be reduced, and design constraints may be eliminated, resulting in an increased degree of freedom in design.

In the display device 100 according to an embodiment of the present disclosure, although the optical electronic device 11 is hidden and located behind the display panel 110, the optical electronic device 11 must normally receive light and perform a predefined function properly.

In addition, in the display device 100 according to an embodiment of the present disclosure, although the optical electronic device 11 is hidden behind the display panel 110 and is overlapped with the display area DA, normal image display must be possible in the optical area OA that overlaps the optical electronic device 11 in the display area DA.

Meanwhile, the display device 100 according to an embodiment of the present disclosure may be applied in various cases. For example, the display device 100 may be applied to a mobile communication device such as a smartphone. Alternatively, the display device 100 may be applied to a vehicle display device.

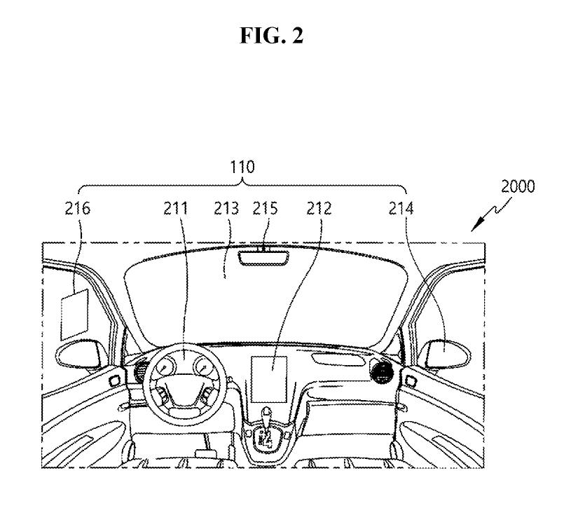

FIG. 2 is a view illustrating a case in which the display device 100 according to an embodiment of the present disclosure is applied to a vehicle 2000.

Referring to FIG. 2, the interior of the vehicle 2000 according to an embodiment of the present disclosure includes a driver’s seat and a passenger seat, and includes a dashboard located in front of the driver’s seat and the passenger seat, where various instruments necessary for driving are arranged.

The dashboard may include a dashboard display panel 211, which displays driving information including a speedometer, and a center fascia in which a control panel for electronic devices installed inside the vehicle 2000 is provided.

The center fascia may be located between the driver’s seat and the passenger seat, and may correspond to a region where the dashboard and a shift lever meet vertically. Various components such as an audio, air conditioner, heater controller, navigator, air vent, cigarette lighter socket, ashtray, and cup holder may be arranged.

Meanwhile, various types of display panels 110 may be installed inside the vehicle 2000, and the plurality of display panels 110 may be installed in different locations to display different types of information. In particular, the plurality of display panels 110 may be classified by type depending on the installation location.

For example, the plurality of display panels 110 may include at least one of a dashboard display panel 211, a center fascia display panel 212, a front window display panel 213, a side mirror display panel 214, a rearview mirror display panel 215, and a side window display panel 216, and various other types of display panels may also be installed.

The dashboard display panel 211 may be a display panel that allows safe operation of the vehicle 2000 by providing a driver with information related to the driving status of the vehicle 2000 and the operation of various electronic devices provided in the vehicle 2000. The dashboard display panel 211 may be located behind a steering wheel based on the driver’s seat and may display a speedometer indicating a driving speed, a trip meter indicating a travel distance, a tachometer indicating engine speed, a fuel gauge, a water temperature gauge, an engine temperature gauge, and various warning lamps.

A display panel disposed between the driver’s seat and the passenger seat of the vehicle 2000 may be referred to as a center fascia display panel 212.

The center fascia display panel 212 may provide a navigation route to a destination or display a map image corresponding to a current location. It may also display a user interface related to control of various electronic devices installed in the vehicle 2000. Furthermore, when a mobile terminal is connected to the vehicle 2000, a screen provided by the mobile terminal may be displayed.

The front window display panel 213 may project a virtual image onto a portion of a front window through which the front of the vehicle 2000 is visible. The front window display panel 213 may display information such as vehicle speed, remaining fuel, and navigation guidance, thereby minimizing the need for the driver to divert attention.

The side mirror display panel 214 may display an image of the side of the vehicle 2000, captured by a side-mounted camera, either on a portion or entire area of a side mirror formed to view the side of the vehicle. Accordingly, the driver may view not only the reflected side image via the side mirror but also the image captured by the side-mounted camera through the side mirror display panel 214.

The rearview mirror display panel 215 may display an image of the rear of the vehicle 2000, captured by a rear camera, on a portion or entire area of a rearview mirror formed to view the rear of the vehicle. Accordingly, the driver may view not only the reflected rear image via the rearview mirror but also the image captured by the rear camera through the rearview mirror display panel 215.

The side window display panel 216 may project a virtual image onto a portion of a side window through which the side of the vehicle 2000 is visible. The side window display panel 216 may display various types of information related to the vehicle.

The display panel 110 according to an embodiment of the present disclosure may be applied to a mobile communication device such as a smartphone or the vehicle 2000 shown in FIG. 2, but is not limited thereto.

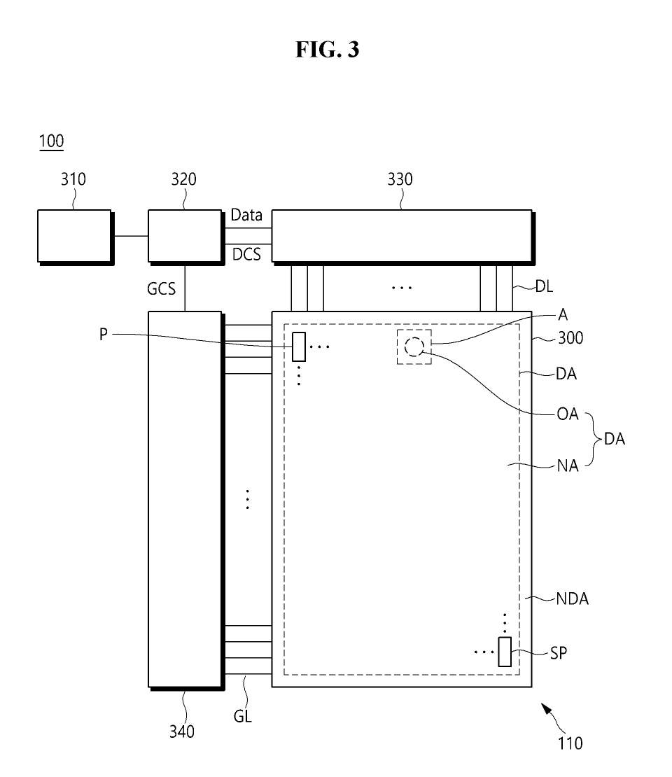

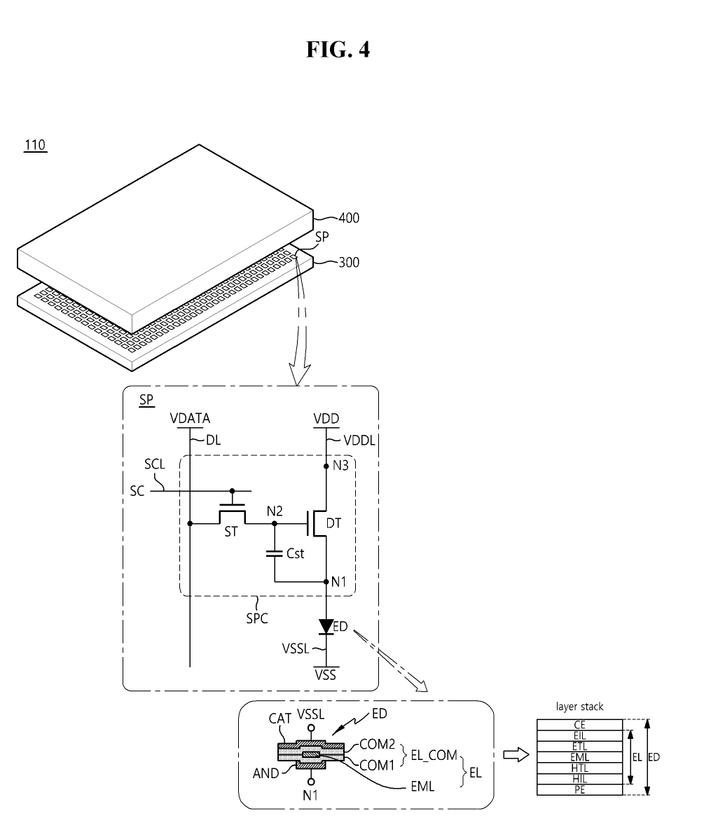

FIG. 3 is a system configuration diagram of a display device 100 according to an embodiment of the present disclosure.

Referring to FIG. 3, the display device 100 may include, as components for image display, the display panel 110, and a display driving circuit.

The display driving circuit may be configured to drive the display panel 110 and may include a data driving circuit 330, a gate driving circuit 340, and a timing controller 320.

The display panel 110 may include a display area DA in which an image is displayed and a non-display area NDA in which an image is not displayed. The non-display area NDA may be located around the outer perimeter of the display area DA and may also be referred to as a bezel area. All or a portion of the non-display area NDA may be visible from the front surface of the display device 100, or it may be a bent portion that is not visible from the front surface.

The display panel 110 may include a substrate 300 and a plurality of sub-pixels SP disposed on the substrate 300. The display panel 110 may further include various types of signal lines configured to drive the plurality of sub-pixels SP.

The display device 100 according to an embodiment of the present disclosure may be a self-emissive display device in which the display panel 110 generates light by itself. However, the display device 100 is not limited to a self-emissive display device.

A plurality of data lines DL and a plurality of gate lines GL may intersect one another. Each of the plurality of data lines DL may be arranged to extend in a first direction. Each of the plurality of gate lines GL may be arranged to extend in a second direction. The first direction may correspond to a column direction and the second direction may correspond to a row direction, or vice versa.

The data driving circuit 330 may drive the plurality of data lines DL and may output data signals to the plurality of data lines DL. The gate driving circuit 340 may drive the plurality of gate lines GL and may output gate signals to the plurality of gate lines GL.

The timing controller 320 may control the data driving circuit 330 and the gate driving circuit 340, and may regulate the driving timing of the plurality of data lines DL and the plurality of gate lines GL.

The timing controller 320 may supply a data driving control signal DCS to the data driving circuit 330 to control the data driving circuit 330, and may supply a gate driving control signal GCS to the gate driving circuit 340 to control the gate driving circuit 340.

For example, the gate driving control signal GCS may include a gate start signal indicating initiation of a gate driving operation, and a reset signal for resetting a voltage applied to the gate driving circuit 340.

The timing controller 320 may receive input image data from a host system 310 and supply image data Data to the data driving circuit 330 based on the input image data.

The data driving circuit 330 may receive image data Data in digital form from the timing controller 320, convert the received image data Data into data signals in analog form, and output the data signals to the plurality of data lines DL.

The gate driving circuit 340 may receive a first gate voltage corresponding to a turn-on level voltage and a second gate voltage corresponding to a turn-off level voltage, along with various gate driving control signals GCS, generate gate signals, and supply the generated gate signals to the plurality of gate lines GL.

The display device 100 may further include a power supply circuit configured to provide various power sources to the display driving circuit.

The display device 100 according to an embodiment of the present disclosure may be implemented as a mobile terminal such as a smartphone or a tablet, a monitor or television (TV) of various sizes, or a vehicle display device, but is not limited thereto. The display device 100 may be any type or size of display capable of outputting information or images.

As described above, the display area DA of the display panel 110 may include a general area NA and an optical area OA. The general area NA and the optical area OA may be configured to display images. However, the general area NA may be an area where a light transmission structure does not need to be formed, and the optical area OA may be an area where a light transmission structure must be formed.

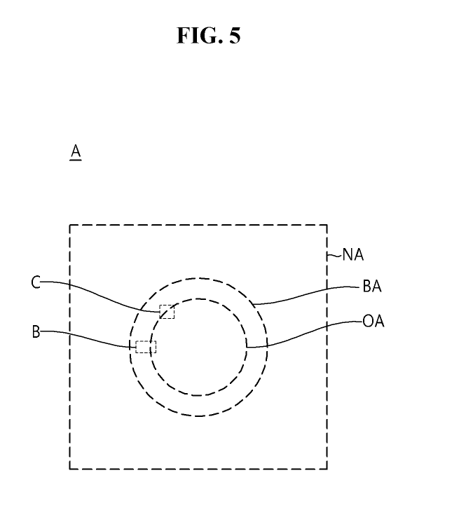

FIG. 4 is a view illustrating the display panel 110 according to an embodiment of the present disclosure.

Referring to FIG. 4, a plurality of sub-pixels SP may be disposed in the display area DA of the display panel 110. The plurality of sub-pixels SP may be disposed in the general area NA and the optical area OA included in the display area DA.

The plurality of sub-pixels SP may be combined in an arbitrary number to form a single pixel.

Referring to FIG. 4, each of the plurality of sub-pixels SP may include a light-emitting device ED and a sub-pixel circuit SPC configured to drive the light-emitting device ED.

Referring to FIG. 4, the sub-pixel circuit SPC may include a driving transistor DT configured to drive the light-emitting device ED, a scan transistor ST configured to deliver a data voltage VDATA to the driving transistor DT, and a storage capacitor Cst configured to maintain a constant voltage for one frame.

The driving transistor DT may include a first node N1, a second node N2, and a third node N3. The first node N1 may be connected to the light-emitting device ED. The second node N2 may be connected to the scan transistor ST. The third node N3 may be connected to a driving voltage line VDDL. The first node N1 may be electrically connected to a pixel electrode PE of the light-emitting device ED. The data voltage VDATA may be applied to the second node N2. The driving voltage VDD may be applied to the third node N3. The first node N1 may be a source node or a drain node, the second node N2 may be a gate node, and the third node N3 may be a drain node or a source node. Hereinafter, for convenience of description, the first node N1 of the driving transistor DT may be assumed to be a source node, the second node N2 to be a gate node, and the third node N3 to be a drain node.

The light-emitting device ED may include a pixel electrode PE, an intermediate layer EL, and a common electrode CE. The pixel electrode PE may be an electrode disposed in each sub-pixel SP. For example, the pixel electrode PE may be electrically connected directly or indirectly (through another transistor) to the first node N1 of the driving transistor DT of each sub-pixel SP. The common electrode CE may be an electrode commonly disposed in the plurality of sub-pixels SP. For example, the common electrode CE may receive a base voltage VSS, which is one type of common driving voltage, through a base voltage line VSSL. For example, the pixel electrode PE may be an anode electrode, and the common electrode CE may be a cathode electrode. Conversely, the pixel electrode PE may be a cathode electrode, and the common electrode CE may be an anode electrode. Hereinafter, for convenience of description, it is assumed that the pixel electrode PE is an anode electrode AE and the common electrode CE is a cathode electrode CE.

The intermediate layer EL may include an emission layer EML and a common intermediate layer EL_COM.

The emission layer EML may be disposed in a light-emitting region of each of the plurality of sub-pixels SP. For example, the emission layer EML may be disposed only in each of the plurality of sub-pixels SP. In another example, the emission layer EML may be commonly disposed in the plurality of sub-pixels SP. In another example, the emission layer EML may be disposed only in the light-emitting region. In another example, the emission layer EML may be disposed in both the light-emitting and non-light-emitting regions.

The common intermediate layer EL_COM may be commonly disposed across the plurality of sub-pixels SP. The common intermediate layer EL_COM may be commonly disposed across the plurality of light-emitting regions EA and non-light-emitting regions.

The common intermediate layer EL_COM may include a first common intermediate layer COM1 and a second common intermediate layer COM2. The first common intermediate layer COM1 may be disposed between the pixel electrode PE and the emission layer EML and may include at least one layer (e.g., an organic layer). The second common intermediate layer COM2 may be disposed between the emission layer EML and the common electrode CE and may include at least one layer (e.g., an organic layer).

For example, the first common intermediate layer COM1 may include a hole injection layer HIL and a hole transfer layer HTL. The second common intermediate layer COM2 may include an electron transfer layer ETL and an electron injection layer EIL. The hole injection layer HIL may inject holes from the pixel electrode PE to the hole transfer layer HTL, and the hole transfer layer HTL may transfer holes to the emission layer EML. The electron injection layer EIL may inject electrons from the common electrode CE to the electron transfer layer ETL, and the electron transfer layer ETL may transfer electrons to the emission layer EML. However, in addition to the hole injection layer HIL, hole transfer layer HTL, electron injection layer EIL, and electron transfer layer ETL described above, other layers may also be included in the first common intermediate layer COM1 and the second common intermediate layer COM2. This may depend on a typical OLED device structure.

Each light-emitting device ED may be formed by an overlapping portion of the pixel electrode PE, the emission layer EML in the intermediate layer EL, and the common electrode CE. A predetermined light-emitting region EA may be formed by each light-emitting device ED. For example, the light-emitting region EA may be defined as a region in which the pixel electrode PE, the emission layer EML of the intermediate layer EL, and the common electrode CE overlap. For example, the light-emitting device ED may be an organic light-emitting diode (OLED), an inorganic light-emitting diode, or a quantum dot light-emitting device. When the light-emitting device ED is an OLED, the intermediate layer EL of the light-emitting device ED may include an organic layer containing organic material.

The scan transistor ST may be turned on and off by a scan signal SC, which is one type of gate signal applied through a scan signal line SCL, which is one type of gate line GL, and may be electrically connected between the second node N2 of the driving transistor DT and the data line DL.

The storage capacitor Cst may be electrically connected between the first node N1 and the second node N2 of the driving transistor DT.

The sub-pixel circuit SPC may have a 2T1C structure including two transistors DT and ST and one capacitor Cst, as shown in FIG. 4. In some cases, it may further include one or more than two transistors or one or more capacitors.

The storage capacitor Cst may be an external capacitor designed outside the driving transistor DT, rather than a parasitic capacitor (e.g., Cgs, Cgd), which is an internal capacitor existing between the first node N1 and the second node N2 of the driving transistor DT. Each of the driving transistor DT and the scan transistor ST may be an n-type transistor or a p-type transistor.

Because the circuit elements in each sub-pixel SP (particularly, the light-emitting device ED implemented as an organic light-emitting diode (OLED) including organic material) are vulnerable to external moisture or oxygen, an encapsulation layer 400 may be disposed in the display panel 110 to prevent external moisture or oxygen from penetrating the circuit elements (particularly, the light-emitting device ED). The encapsulation layer 400 may be disposed to cover the light-emitting devices ED.

FIG. 5 is a plan view showing an enlarged view of area A shown in FIG. 3.

The display device 100 according to an embodiment of the present disclosure may include a boundary area BA.

Referring to FIG. 5, the boundary area BA may be an area disposed between the optical area OA and the general area NA. The boundary area BA may be an area capable of displaying an image, like the general area NA and the optical area OA. Furthermore, the boundary area BA may be an area in which a light transmission structure does not need to be formed, like the general area NA.

Accordingly, the boundary area BA may have no light transmittance or may have low transmittance below a certain level.

For example, the general area NA and the boundary area BA may have the same resolution, sub-pixel SP arrangement structure, number of sub-pixels SP per unit area, electrode structure, line structure, electrode arrangement structure, or line arrangement structure.

For example, the number of sub-pixels per unit area in the boundary area BA may be the same as that in the general area NA and greater than that in the optical area OA. In particular, the resolution of the boundary area BA may be higher than that of the optical area OA.

Meanwhile, although the boundary area BA may have the same resolution, sub-pixel SP arrangement structure, number of sub-pixels SP per unit area, electrode structure, line structure, electrode arrangement structure, or line arrangement structure as the general area NA, the image displayed in the boundary area BA may mimic characteristics of the image displayed in the optical area OA.

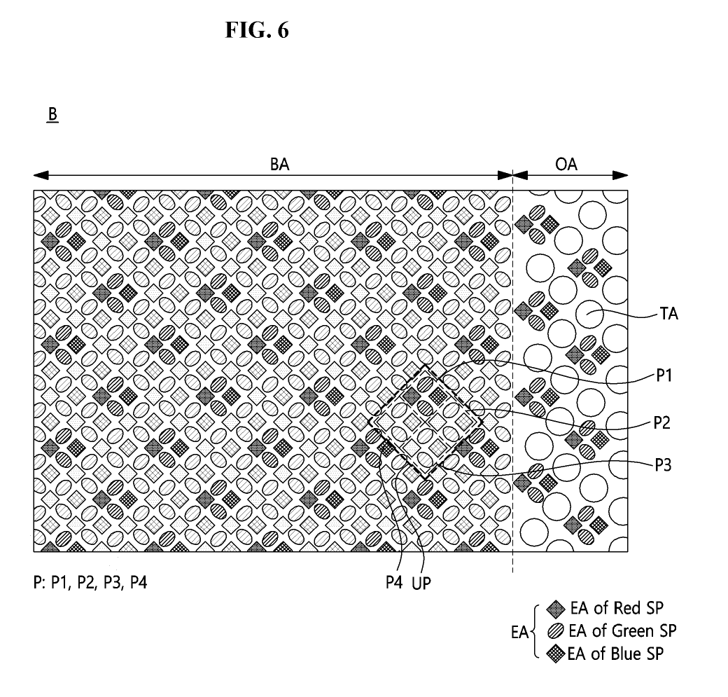

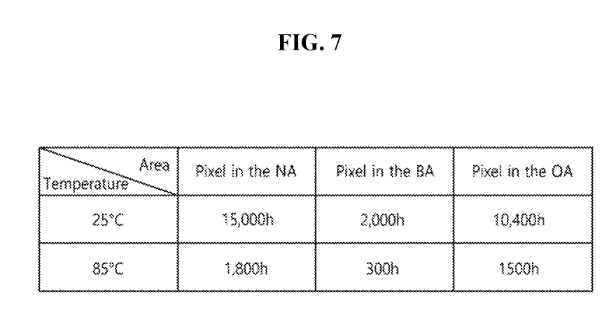

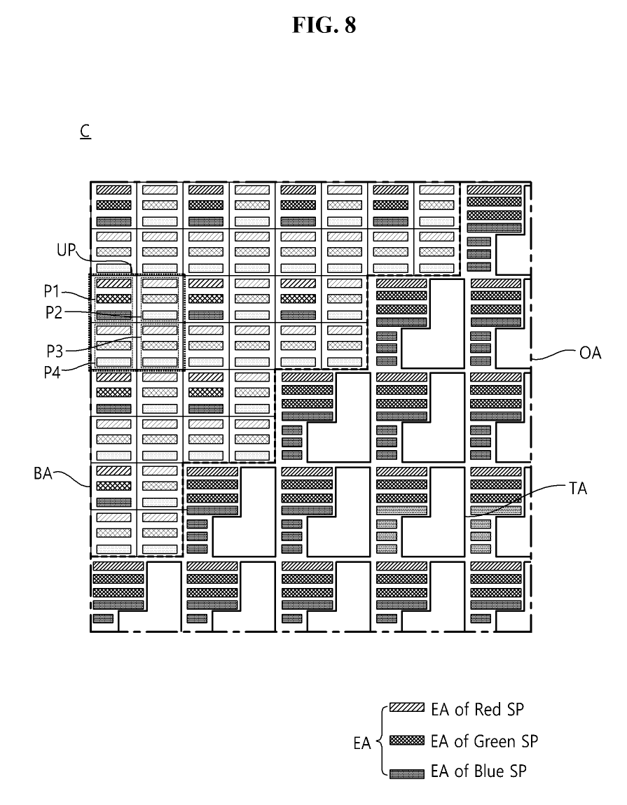

FIG. 6 is a view illustrating sub-pixels SP disposed in the boundary area BA and the optical area OA in area B shown in FIG. 5.

Because the boundary area BA, like the general area NA, does not need to have a light transmission structure, a sub-pixel SP may be disposed without a transmissive area TA. Referring to FIG. 6, the light-emitting region EA of a red sub-pixel corresponds to the red sub-pixel, the light-emitting region EA of a green sub-pixel corresponds to the green sub-pixel, and the light-emitting region EA of a blue sub-pixel corresponds to the blue sub-pixel. Hereinafter, for convenience of description, each light-emitting region EA of a sub-pixel is described as corresponding to the sub-pixel SP.

In the boundary area BA, one red sub-pixel, two green sub-pixels, and one blue sub-pixel may constitute one pixel P. The configuration of the sub-pixels SP included in one pixel P is merely an example for explanation and is not limited thereto.

Four pixels P may form one unit pixel UP. Referring to FIG. 6, an arbitrary unit pixel UP may include a first pixel P1, a second pixel P2, a third pixel P3, and a fourth pixel P4.

In the embodiment of the present disclosure, it is defined for convenience of explanation that one unit pixel UP includes four pixels P, but this is merely an assumption for explanation and is not limited thereto. For example, the unit pixel UP may include at least two pixels P. Hereinafter, it is assumed that one unit pixel UP includes four pixels P for explanation.

In the boundary area BA, such unit pixels UP may be disposed in the same form and configuration as in the general area NA.

Meanwhile, the optical area OA may include sub-pixels SP corresponding to light-emitting regions EA and transmissive areas TA.

The light-emitting regions EA and the transmissive area TA may be distinguished based on whether light can be transmitted. In particular, the light-emitting regions EA may be areas where light transmission is not possible, and the transmissive area TA may be an area where light transmission is possible.

In addition, the light-emitting regions EA and the transmissive area TA may be distinguished based on the presence or absence of formation of a specific metal layer CE. For example, the common electrode CE may be formed in the light-emitting regions EA, and may not be formed in the transmissive area TA. A light shield layer may be formed in the light-emitting regions EA, and may not be formed in the transmissive area TA.

Because the optical area OA may include the transmissive area TA, the optical area OA may be an area through which light can be transmitted.

Also, as shown in FIG. 6, in the embodiments of the present disclosure, the transmissive area TA may also be referred to as a transparent area, and its transmittance may also be referred to as transparency.

Referring to FIG. 6, in an area corresponding to a unit pixel UP of the boundary area BA, the boundary area BA may include four pixels P, and the optical area OA may include one pixel P and three transmissive areas TA. However, this is merely an example for ease of explanation, and the number of pixels P included in the unit pixel UP of the boundary area BA and the ratio of pixels P to transmissive areas TA in the optical area OA are not limited thereto and may be variously set.

For example, to further increase the transmittance in the optical area OA, the ratio of transmissive areas TA may be increased, and to increase the resolution, the ratio of pixels P may be increased. In the embodiment of the present disclosure, it is assumed that the number ratio of pixels P to transmissive areas TA is 1:3, as shown in FIG. 6.

Because the transmissive area TA is disposed in the transmissive area TA, transmittance may be increased, and light may be delivered to the optical electronic device 11 disposed in the transmissive area TA. However, because the pixel P arrangement in the boundary area BA differs from that in the optical area OA, a boundary line may be visible at the boundary where the boundary area BA and the optical area OA meet.

In addition, because the optical area OA may include a structure in which pixels P and transmissive areas TA are arranged in a 1:3 ratio, a user may perceive a sense of grid pattern. To compensate for luminance degradation caused by the reduced number of pixels P within the optical area OA, the luminance of the pixels P disposed in the optical area OA may be set higher than that in the general area NA, in particular, in a high luminance state. This perceived grid pattern may further increase a user’s sense of heterogeneity between the boundary area BA and the optical area OA.

Accordingly, in order to prevent visibility of a boundary line between the boundary area BA and the optical area OA, the luminance of each pixel P included in the unit pixel UP may be adjusted in the boundary area BA adjacent to the optical area OA.

Referring to FIG. 6, the unit pixel UP of the boundary area BA may include a first pixel P1, a second pixel P2, a third pixel P3, and a fourth pixel P4. In this case, the first pixel P1 of the unit pixel UP, which is adjacent to the optical area OA, may emit light in a high luminance state at the same level as the pixel P in the optical area OA. The second pixel P2, the third pixel P3, and the fourth pixel P4, exclusive of the first pixel P1, may emit light in a low luminance state that is lower than the luminance of the first pixel P1. In other words, the second pixel P2, the third pixel P3, and the fourth pixel P4 may emit light in a low luminance state that is darker than the luminance of the first pixel P1.

Through such a light-emitting structure of the unit pixel UP, the characteristics of the image output in the optical area OA, i.e., characteristics resulting from the 1:3 ratio of pixels P and transmissive areas TA, may be mimicked.

In addition, the pixels P that emit light in a high luminance state within the boundary area BA may be configured such that their luminance gradually decreases as their distance from the optical area OA increases, thereby matching the luminance of the pixels P disposed in the general area NA. Likewise, the pixels P that emit light in a low luminance state within the boundary area BA may be configured such that their luminance gradually increases as their distance from the optical area OA increases, thereby matching the luminance of the pixels P in the general area NA.

In particular, the pixels P disposed in the boundary area BA may emit light in a high or low luminance state to mimic the layout characteristics of pixels P and transmissive areas TA disposed in the optical area OA, and their luminance may be gradually adjusted to match that of the pixels P disposed in the general area NA as the distance from the optical area OA increases, thereby preventing the visibility of a boundary line between the optical area OA and the boundary area BA.

However, because the first pixel P1 included in an arbitrary unit pixel UP in the boundary area BA emits light in a high luminance state during the image display period, its lifespan may be shortened compared to other pixels P.

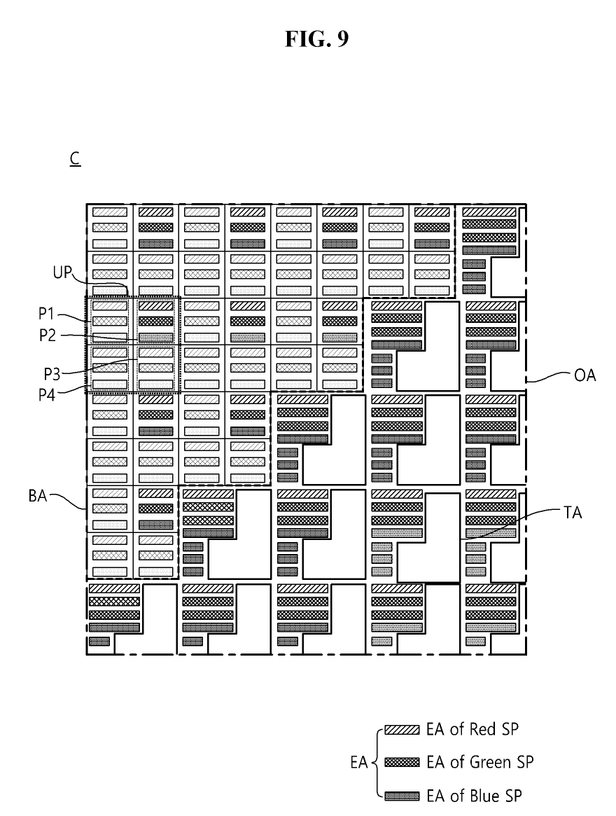

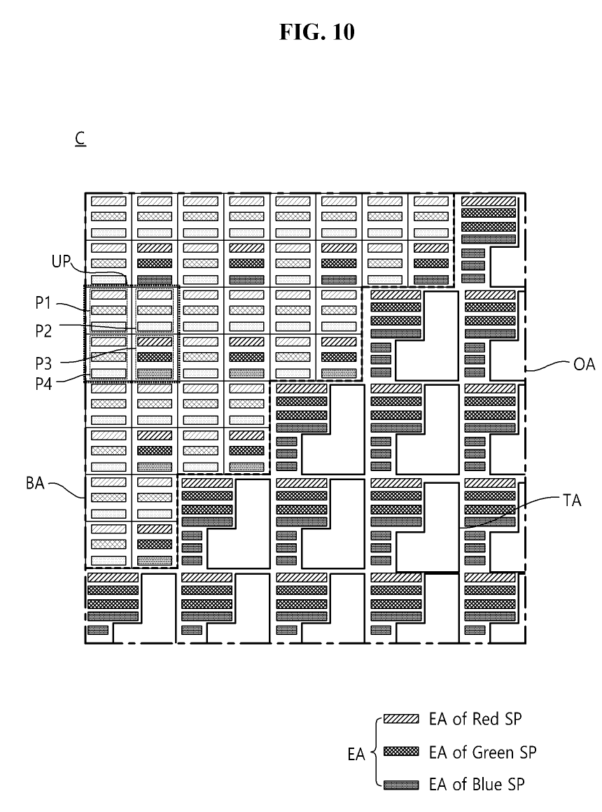

FIG. 7 is a table showing a simulation result of expected lifespans by temperature for the pixels P disposed in the general area NA, the boundary area BA, and the optical area OA.

The pixel in the BA shown in FIG. 7 may refer to the first pixel P1 that emits light in a high luminance state as shown in FIG. 6.

Referring to FIG. 7, the expected lifespan of a pixel P disposed in the general area NA at 25°C may be 15,000 hours. The expected lifespan of a pixel P disposed in the optical area OA at 25°C may be 10,400 hours. However, the expected lifespan of the first pixel P1, which emits light in a high luminance state and is disposed in the boundary area BA, may be 2,000 hours at 25°C, which is significantly shorter than the pixels P disposed in the general area NA and the optical area OA.

In addition, referring to FIG. 7, the expected lifespan of a pixel P disposed in the general area NA at 85°C may be 1,800 hours. The expected lifespan of a pixel P disposed in the optical area OA at 85°C may be 1,500 hours. However, the expected lifespan of the first pixel P1, which emits light in a high luminance state and is disposed in the boundary area BA, may be 300 hours at 85°C, which is significantly shorter than the pixels P disposed in the general area NA and the optical area OA.

Accordingly, in order to extend the lifespan of the pixels P in the boundary area BA, the pixels P in the boundary area BA may be sequentially driven.

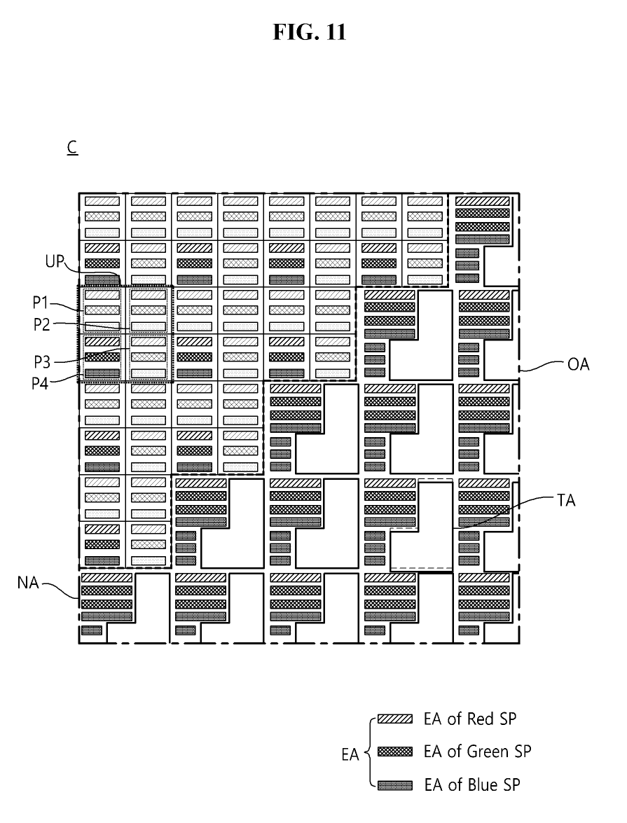

FIGS. 8, 9, 10, and 11 are views illustrating a feature in which the pixels P disposed in the boundary area BA are sequentially driven in area C shown in FIG. 5.

Referring to FIGS. 8, 9, 10, and 11, area C may include the boundary area BA and the optical area OA. The boundary area BA may include unit pixels UP. The unit pixel UP may include a first pixel P1, a second pixel P2, a third pixel P3, and a fourth pixel P4.

In the following description, the red sub-pixel may be assumed to correspond to the red sub-pixel light-emitting region EA of Red SP, the green sub-pixel to the green sub-pixel light-emitting region EA of Green SP, and the blue sub-pixel to the blue sub-pixel light-emitting region EA of Blue SP. In particular, the sub-pixels SP and the light-emitting regions EA may be assumed to have a one-to-one correspondence.

Each pixel P may include a red sub-pixel light-emitting region EA of Red SP, a green sub-pixel light-emitting region EA of Green SP, and a blue sub-pixel light-emitting region EA of Blue SP. However, this is merely an example for ease of explanation, and the number and arrangement of the light-emitting regions EA by color may be variously implemented. Hereinafter, it is assumed that one red sub-pixel, one green sub-pixel, and one blue sub-pixel are disposed in the pixel P in the boundary area BA.

Referring to FIGS. 8, 9, 10, and 11, the optical area OA may include light-emitting regions EA and transmissive areas TA. In the area of the optical area OA corresponding to the unit pixel UP in the boundary area BA, one red sub-pixel, two green sub-pixels, four blue sub-pixels, and one transmissive area TA may be disposed. However, this is merely an example for describing that the number and layout of pixels P, the number and layout of the optical areas OA, etc., may be variously configured for adjusting the transmittance in the optical area OA, and is not limited to the examples shown in FIGS. 8, 9, 10, and 11.

The characteristics of the light-emitting regions EA and the transmissive areas TA in the optical area OA shown in FIGS. 8, 9, 10, and 11, may be interpreted in the same context as the characteristics of the light-emitting regions EA and the transmissive areas TA in the optical area OA shown in FIG. 6. In particular, because the optical area OA includes the light-emitting regions EA and the transmissive areas TA, the number and arrangement of sub-pixels SP per unit area may differ from those in the general area NA and the boundary area BA due to the smaller number of sub-pixels SP per unit area. In addition, the transmissive area TA is an area formed for transmitting light, and may be arranged in a predetermined ratio relative to the sub-pixels SP disposed in the optical area OA.

Referring to FIG. 8, the unit pixel UP disposed in the boundary area BA may include the first pixel P1 that emits light in a high luminance state, and the second pixel P2, the third pixel P3, and the fourth pixel P4 that emits light in a low luminance state, in order to mimic the characteristics of an image displayed in the optical area OA.

Thereafter, the pixels P that emits light in a high luminance state and the pixels P that emits light in a low luminance state may be sequentially switched according to a predetermined timing by the timing controller 320.

Referring to FIG. 9, after the light-emitting state of the unit pixel UP shown in FIG. 8, the second pixel P2 of the unit pixel UP may emit light in a high luminance state. The first pixel P1, the third pixel P3, and the fourth pixel P4 of the unit pixel UP may emit light in a low luminance state. Thereafter, the pixels P that emits light in a high luminance state and the pixels P that emits light in a low luminance state may be sequentially switched according to a predetermined timing by the timing controller 320.

Referring to FIG. 10, after the light-emitting state of the unit pixel UP shown in FIG. 9, the third pixel P3 of the unit pixel UP may emit light in a high luminance state. The first pixel P1, the second pixel P2, and the fourth pixel P4 of the unit pixel UP may emit light in a low luminance state. Thereafter, the pixels P that emits light in a high luminance state and the pixels P that emits light in a low luminance state may be sequentially switched according to a predetermined timing by the timing controller 320.

Referring to FIG. 11, after the light-emitting state of the unit pixel UP shown in FIG. 10, the fourth pixel P4 of the unit pixel UP may emit light in a high luminance state. The first pixel P1, the second pixel P2, and the third pixel P3 of the unit pixel UP may emit light in a low luminance state. Thereafter, the pixels P that emits light in a high luminance state and the pixels P that emits light in a low luminance state may be sequentially switched according to a predetermined timing by the timing controller 320.

After the fourth pixel P4 emits light in a high luminance state and the remaining first pixel P1, second pixel P2, and third pixel P3 emit light in a low luminance state, the light-emitting state may return to that shown in FIG. 8. In particular, as shown in FIG. 8, the first pixel P1 may emit light in a high luminance state, and the remaining second pixel P2, third pixel P3, and fourth pixel P4 may emit light in a low luminance state.

After returning to the light-emitting state of the unit pixel UP shown in FIG. 8, the process shown in FIGS. 8, 9, 10, and 11 may be continuously repeated.

As shown in FIGS. 8, 9, 10, and 11, by sequentially switching the pixel P that emits light in a high luminance state within the unit pixel UP at a predetermined timing, it is possible to achieve an effect of solving the problem of lifespan degradation of a specific pixel P, which used to occur due to concentration of high-luminance operation on a particular pixel P in the unit pixel UP.

In the foregoing description of the embodiments of the present disclosure, one of the four pixels P included in the unit pixel UP is assumed to emit light in a high luminance state and the other three in a low luminance state, but this is merely for convenience of explanation and is not limited thereto. For example, the pixels P that emits light in a high or low luminance state in the unit pixel UP may be controlled in various patterns to mimic the light-emitting pattern in the optical area OA. For instance, when the ratio of pixels P to transmissive areas TA in the optical area OA is 1:1, two pixels P may emit light in a high luminance state and two pixels P in a low luminance state in the unit pixel UP of the boundary area BA.

Meanwhile, the high and low luminance states described in FIGS. 8, 9, 10, and 11 may gradually vary depending on the distance from the optical area OA.

The pixels P that emits light in a high luminance state in the boundary area BA may be set to gradually decrease in luminance as they become farther from the optical area OA, so that their luminance becomes equal to that of the pixels P disposed in the general area NA. Similarly, the pixels P that emits light in a low luminance state in the boundary area BA may be set to gradually increase in luminance as they become farther from the optical area OA, so that their luminance becomes equal to that of the pixels P disposed in the general area NA.

In particular, the pixels P disposed in the boundary area BA may emit light in a high or low luminance state to mimic the layout characteristics of the pixels P and the transmissive areas TA in the optical area OA, and the luminance may be gradually adjusted to become equal to that of the pixels P disposed in the general area NA as the distance from the optical area OA increases, thereby preventing the visibility of a boundary line between the optical area OA and the boundary area BA.

Meanwhile, the timing controller 320 may count a start signal of the display device 100 in order to determine a timing point at which the luminance of the pixel P that emits light in a high luminance state is to be changed sequentially.

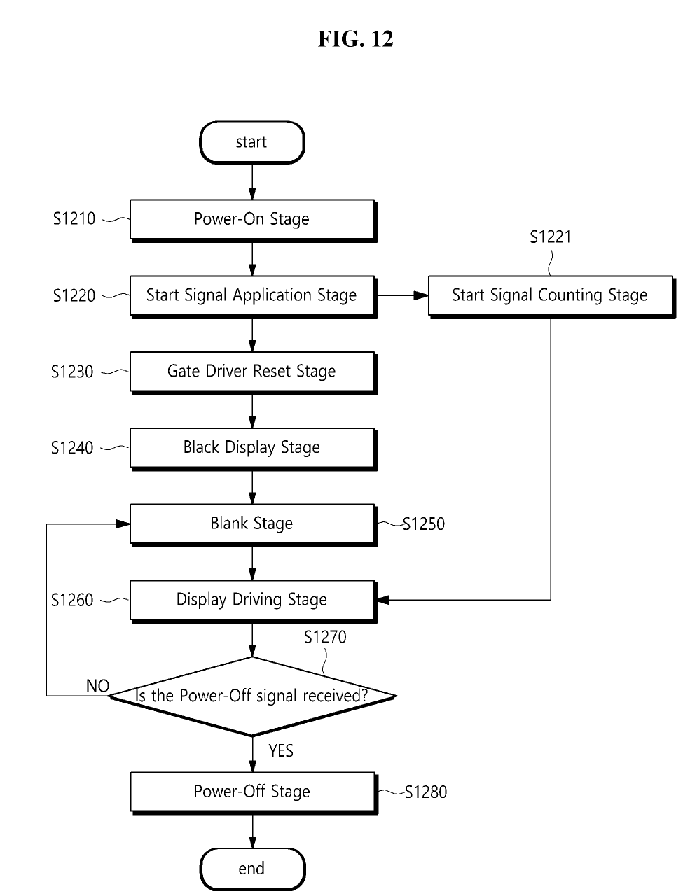

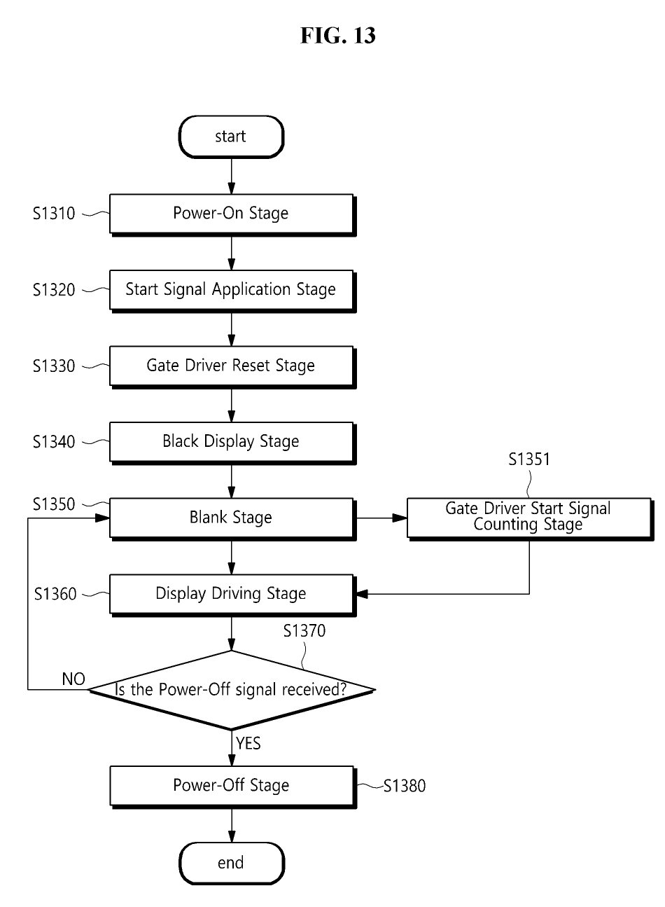

FIG. 12 and FIG. 13 are flowcharts illustrating a driving method of the display device 100 for controlling the timing of changing the luminance of the pixel P that emits light in a high luminance state.

Referring to FIG. 12, the start signal counted by the timing controller 320 may be a signal generated when power is applied to the display device 100 and the timing controller 320 is initially powered on and begins operation.

Referring to FIG. 12, firstly, power may be applied to the display device 100 (S1210).

After power is applied to the display device 100, power may be supplied to the timing controller 320. In this case, the timing controller 320 may begin operation and generate a start signal for the first time (S1220).

The generated start signal may be counted and accumulated (or incremented) in a memory (not shown) disposed in the timing controller 320 (S1221). The counted and accumulated (or incremented) value may be accumulated (or incremented) within a limited range corresponding to the number of pixels P included in the unit pixel UP of the boundary area BA. For example, when the unit pixel UP includes four pixels P, the stored value may range from 1 to 4 and may be cyclically accumulated (or incremented) starting again from 1 after reaching the maximum value.

Thereafter, the timing controller 320 may reset the entire gate driving circuit 340 in order to initialize the state of the gate driving circuit 340 (S1230). Specifically, the timing controller 320 may apply an initialization signal to the gate driving circuit 340 to discharge the nodes in the gate driving circuit 340 to an initial state or to set the nodes to a predetermined reference voltage. When this reset process is completed, the gate driving circuit 340 may be in an initial state capable of normal driving.

After the initialization of the gate driving circuit 340 is completed, a step of displaying a black screen on the display panel 110 may be performed (S1240). Specifically, the data driving circuit 330 may set the data voltage supplied to the display panel to a black screen state. Typically, the black screen may be implemented by supplying a data voltage that minimizes emission in all sub-pixels SP. In addition, the gate driving circuit 340 may apply a gate signal suitable for the black screen state.

By maintaining the black screen for a predetermined time before displaying an image on the display panel 110 while the display device 100 is operating, afterimages of the previous frame, which may be caused by a capacitance effect in the display panel 110, may be minimized. When this step is completed, the display device may be in a ready state for normal driving.

After the black screen is displayed, a blank stage and a display driving stage may be repeated until power is turned off in the display device 100 to display an image.

The blank stage may be a stage in which an image is not displayed (S1250). Specifically, in one frame of an image, this stage may be for preparing the image output for the next frame or for initializing the panel and circuits.

The display driving stage may be a stage of actually displaying an image on the display panel 110 after the blank stage ends (S1260). Specifically, the gate driving circuit 340 may sequentially apply gate signals to each gate line to select and activate a row. For the selected row, the data driving circuit 330 may output a data voltage that determines the brightness and color of each pixel P so that the image is displayed.

In this case, the timing controller 320 may control the pixels P disposed in the boundary area BA based on a counted value obtained by accumulating a start signal stored in a memory (not shown). Specifically, in the case where each unit pixel UP disposed in the boundary area BA includes four pixels P, namely the first pixel P1, the second pixel P2, the third pixel P3, and the fourth pixel P4, the timing controller 320 may store a counting signal having a value that cyclically accumulates between 1 and 4 depending on the number of times the start signal has been generated.

Based on the stored counting signal, the luminance of the pixels P in the unit pixel UP disposed in the boundary area BA may be adjusted during the display driving stage (S1260).

For example, when the counting signal has a value of 1, the first pixel P1 in the unit pixel UP may emit light in a high luminance state, and the second pixel P2, the third pixel P3, and the fourth pixel P4 may emit light in a low luminance state.

When the counting signal has a value of 2, the second pixel P2 in the unit pixel UP may emit light in a high luminance state, and the first pixel P1, the third pixel P3, and the fourth pixel P4 may emit light in a low luminance state.

When the counting signal has a value of 3, the third pixel P3 in the unit pixel UP may emit light in a high luminance state, and the first pixel P1, the second pixel P2, and the fourth pixel P4 may emit light in a low luminance state.

When the counting signal has a value of 4, the fourth pixel P4 in the unit pixel UP may emit light in a high luminance state, and the first pixel P1, the second pixel P2, and the third pixel P3 may emit light in a low luminance state.

After the counting signal reaches a value of 4, when the start signal is counted and accumulated (or incremented) again, the counting signal may again have a value of 1. Accordingly, the first pixel P1 in the unit pixel UP disposed in the boundary area BA may again emit light in a high luminance state, and the remaining second pixel P2, third pixel P3, and fourth pixel P4 may emit light in a low luminance state, and the subsequent stages may be repeated sequentially.

In particular, according to the above-described driving sequence, when power is applied to the display device 100, the timing controller 320 may generate a start signal and may accumulate a counting signal based on the start signal in accordance with the number of pixels P included in the unit pixel UP disposed in the boundary area BA. As a result, the luminance of the pixels P disposed in the boundary area BA may be controlled based on the counting signal, and the luminance of the pixels P disposed in the boundary area BA may be adjusted whenever the display device is powered on or off, thereby preventing a problem in which a specific pixel P, which is continuously used to mimic the light-emitting characteristics of the optical area OA, is subject to stress and experiences a reduction in lifespan.

Meanwhile, after the display driving stage (S1260), it may be determined whether a power-off signal has been applied from the display device 100 (S1270). If the power-off signal is applied (Yes to S1270), the power may be turned off and the driving of the display device 100 may be stopped (S1280). If the power is not turned off (No to S1270), the process may return to the blank stage (S1250).

As described above, although the timing controller 320 may control the light emission of the pixels P in the boundary area BA by accumulating the counting signal based on the start signal generated whenever the display device 100 transitions from the off state to the on state, the counting signal may also be accumulated (or incremented) based on another signal.

Referring to FIG. 13, the start signal counted by the timing controller 320 may be a start signal applied to the gate driving circuit 340 during a blank section of the display panel 110.

Referring to FIG. 13, first, power may be applied to the display device 100 (S1310).

After power is applied to the display device 100, power may be supplied to the timing controller 320. In this case, the timing controller 320 may begin operation and generate a start signal for the first time (S1320).

Thereafter, the timing controller 320 may reset the entire gate driving circuit 340 in order to set the gate driving circuit 340 to an initial state (S1330). Specifically, the timing controller 320 may apply an initialization signal to the gate driving circuit 340 to discharge the nodes in the gate driving circuit 340 to an initial state or to set them to a predetermined reference voltage. When this reset process is completed, the gate driving circuit 340 may be in an initial state suitable for normal operation.

After the initialization of the gate driving circuit 340 is completed, a step of displaying a black screen on the display panel 110 may be performed (S1340). Specifically, the data driving circuit 330 may set the data voltage supplied to the display panel to a black screen state. Typically, the black screen may be implemented by supplying a data voltage that minimizes emission in all sub-pixels SP. In addition, the gate driving circuit 340 may apply a gate signal suitable for the black screen state.

By operating the display device 100, a black screen may be maintained for a predetermined time before displaying an image on the display panel 110, thereby minimizing an afterimage of a previous frame that may occur due to a capacitance effect inside the display panel 110. When this step is completed, the display device may be in a ready state for normal driving.

After the step of displaying the black screen, the blank stage and the display driving stage may be repeatedly performed to display an image until power is turned off in the display device 100.

The blank stage may be a stage in which no image is displayed (S1350). Specifically, in one frame of an image, this stage may be a preparation stage for outputting the next frame of the image or an initialization process of the panel and circuits.

During the blank stage, in order to ensure normal operation of the gate driving circuit 340 and prepare for driving the next frame, a gate start signal may be applied from the timing controller 320. In particular, for each frame of the image displayed on the display panel 110, a gate start signal may be supplied from the timing controller 320 to the gate driving circuit 340. The gate start signal may serve to initialize the gate driving circuit 340 during the blank interval. In particular, the gate start signal may serve to reset the internal circuit voltage levels of the gate driving circuit 340 to an initial state during the blank interval and to prepare the gate driving circuit 340 to normally output gate signals for the subsequent frame.

The gate start signal may be applied to the gate driving circuit 340 at the beginning of the blank interval, and a value counted for the gate start signal may be accumulated (or incremented) in a memory (not shown) disposed in the timing controller 320 (S1351). The accumulated (or incremented) value may be stored within a limited range based on the number of pixels P included in a unit pixel UP of the boundary area BA. For example, when the number of pixels P included in the unit pixel UP is four, the stored value may range from 1 to 4 and may cyclically accumulate from 1 again after reaching the maximum value.

The display driving stage may be a stage in which an actual image is displayed on the display panel 110 after the blank stage ends (S1360). Specifically, the gate driving circuit 340 may sequentially apply gate signals to each gate line to select and activate a row. For the selected row, the data driving circuit 330 may output a data voltage that determines the brightness and color of the pixels P, so that the image may be displayed.

In this case, the timing controller 320 may control the pixels P disposed in the boundary area BA based on a counting value obtained by accumulating the gate start signal stored in a memory (not shown). Specifically, when each unit pixel UP disposed in the boundary area BA includes four pixels P, namely a first pixel P1, a second pixel P2, a third pixel P3, and a fourth pixel P4, the timing controller 320 may store a counting signal having a value that cyclically accumulates from 1 to 4 in accordance with the accumulated (or incremented) gate start signals.

Based on the stored counting signal, the luminance of the pixels P in the unit pixel UP disposed in the boundary area BA may be adjusted during the display driving stage (S1360).

For example, when the counting signal has a value of 1, the first pixel P1 in the unit pixel UP may emit light in a high luminance state, and the second pixel P2, the third pixel P3, and the fourth pixel P4 may emit light in a low luminance state.

When the counting signal has a value of 2, the second pixel P2 in the unit pixel UP may emit light in a high luminance state, and the first pixel P1, the third pixel P3, and the fourth pixel P4 may emit light in a low luminance state.

When the counting signal has a value of 3, the third pixel P3 in the unit pixel UP may emit light in a high luminance state, and the first pixel P1, the second pixel P2, and the fourth pixel P4 may emit light in a low luminance state.

When the counting signal has a value of 4, the fourth pixel P4 in the unit pixel UP may emit light in a high luminance state, and the first pixel P1, the second pixel P2, and the third pixel P3 may emit light in a low luminance state.

After the counting signal reaches a value of 4, when the start signal is counted and accumulated (or incremented) again, the counting signal may again have a value of 1. Accordingly, the first pixel P1 in the unit pixel UP disposed in the boundary area BA may again emit light in a high luminance state, and the remaining second pixel P2, third pixel P3, and fourth pixel P4 may emit light in a low luminance state, and the subsequent stages may be repeatedly performed in sequence.

In particular, according to the driving sequence described above, the timing controller 320 may accumulate a counting signal corresponding to the number of pixels P included in the unit pixel UP disposed in the boundary area BA based on the gate start signal for initializing the gate driving circuit 340 during the blank stage (S1350). As a result, the luminance of the pixels P disposed in the boundary area BA may be adjusted according to the counting signal, and each time the gate driving circuit 340 is initialized during the blank stage (S1350), the luminance of the pixels P disposed in the boundary area BA may be adjusted, thereby preventing the problem of reduced lifespan of specific pixels P that are excessively stressed due to mimicking the light-emitting characteristics of the optical area OA.

Meanwhile, after the display driving stage (S1360), it may be determined whether a power-off signal has been applied from the display device 100 (S1370). If a power-off signal is applied (Yes to S1370), the power may be turned off and the operation of the display device 100 may be stopped (S1380). If the power is not turned off (No to S1370), the process may return to the blank stage (S1350).

The display device according to the embodiments of the present disclosure may be described as follows.

A display panel including a general area, an optical area through which light can be transmitted, and a boundary area disposed between the general area and the optical area; a unit pixel including at least two pixels disposed in the boundary area, which emits light based on gate signals supplied through a gate driving circuit in the display panel; and a timing controller configured to control the gate driving circuit, wherein at least some of the at least two pixels included in the unit pixel emit light in a high luminance state, and the remaining pixels emit light in a low luminance state, and the high luminance state or the low luminance state of the at least two pixels may be sequentially switched within the unit pixel based on a value of a counting signal generated by the timing controller.

When power is applied to the display panel, the timing controller may supply a start signal, and the value of the counting signal may be a value accumulated (or incremented) each time the start signal is supplied to the timing controller.

The gate driving circuit may receive a gate start signal from the timing controller for each frame of the image displayed on the display panel, and the counting signal may be a value accumulated (or incremented) each time the gate start signal is supplied to the gate driving circuit.

Among the at least two pixels included in the unit pixel, one pixel may emit light in a high luminance state, and the remaining pixels other than the pixel that emits light in the high luminance state may emit light in a low luminance state.

The unit pixel may include N pixels, where N is a natural number equal to or greater than 2, and the value of the counting signal may be accumulated (or incremented) under the control of the timing controller from a value indicating a first state to a value indicating an Nth state. After reaching the value indicating the Nth state, the value may be accumulated (or incremented) again from the value indicating the first state. When the counting signal has the value indicating the first state, a first pixel in the unit pixel may emit light in a high luminance state, and the remaining pixels may emit light in a low luminance state. When the counting signal has the value indicating the Nth state, an Nth pixel in the unit pixel may emit light in a high luminance state, and the remaining pixels may emit light in a low luminance state.

The value of the counting signal may be stored in a memory of the timing controller.

The pixels that emits light in the high luminance state in the boundary area may be controlled such that their luminance gradually decreases as their distance from the optical area increases, and the pixels that emits light in the low luminance state in the boundary area may be controlled such that their luminance gradually increases as their distance from the optical area increases.

The optical area may include a transmissive area through which light can be transmitted, and the transmissive area and the pixels may not be vertically overlapped with each other in the display panel. The optical area may have a smaller number of pixels per unit area than the general area and the boundary area.

An optical electronic device may be disposed in the optical area, and the optical electronic device may perform a predefined operation using light transmitted through the transmissive area.

The display panel may be disposed in a front cluster of an interior of a vehicle.

A timing controller configured to control a unit pixel that includes at least two pixels disposed in a boundary area of a display panel, the display panel comprising a general area, an optical area through which light can be transmitted, and a boundary area disposed between the general area and the optical area, a gate driving circuit for driving the display panel, wherein the unit pixel emits light in response to gate signals supplied through the gate driving circuit, wherein at least some of the at least two pixels included in the unit pixel emit light in a high luminance state, and the remaining pixels emit light in a low luminance state, and the high luminance state or the low luminance state of the at least two pixels may be sequentially switched within the unit pixel according to a value of a counting signal of the timing controller.

When power is applied to the display panel, a start signal may be supplied to the timing controller, and the value of the counting signal may be a value that is accumulated (or incremented) each time the start signal is supplied to the timing controller.

The gate driving circuit may receive a gate start signal from the timing controller for each frame of an image displayed on the display panel, and the counting signal may be a value that is accumulated (or incremented) each time the gate start signal is supplied to the gate driving circuit.

The unit pixel may include N pixels, where N is a natural number equal to or greater than 2, and the value of the counting signal may be accumulated (or incremented) under the control of the timing controller from a value indicating a first state to a value indicating an Nth state. After reaching the value indicating the Nth state, the value may be accumulated (or incremented) again from the value indicating the first state. When the counting signal has the value indicating the first state, a first pixel in the unit pixel may emit light in a high luminance state, and the remaining pixels may emit light in a low luminance state. When the counting signal has the value indicating the Nth state, an Nth pixel in the unit pixel may emit light in a high luminance state, and the remaining pixels may emit light in a low luminance state.

The system may further include a memory in which the value of the counting signal is stored.

The pixels that emits light in the high luminance state in the boundary area may be controlled such that their luminance gradually decreases as their distance from the optical area increases, and the pixels that emits light in the low luminance state in the boundary area may be controlled such that their luminance gradually increases as their distance from the optical area increases.

According to embodiments of the present disclosure, a timing controller may be configured to control: a display panel including a general area, an optical area that is transmissive to light, and a boundary area disposed between the general area and the optical area; a gate driving circuit for driving the display panel; and a unit pixel including at least two pixels that are disposed in the boundary area and emit light by receiving a gate signal through the gate driving circuit, wherein at least some of the at least two pixels included in the unit pixel emit light in a high luminance state, and the remaining pixels emit light in a low luminance state, and the high luminance state or the low luminance state of the at least two pixels may be controlled to sequentially change within the unit pixel according to a value of a counting signal of the timing controller.

According to embodiments of the present disclosure, because a notch or hole for exposing an optical electronic device may be obviated, a display device and a timing controller may have the configuration to enable a reduction in size of a bezel area and improve the degree of freedom in design by eliminating design constraints.

According to embodiments of the present disclosure, a display device and a timing controller may prevent visibility of a boundary line between an optical area and a boundary area by driving pixels disposed in the boundary area to mimic the layout characteristics of pixels disposed in the optical area and the transmissive area, and by gradually adjusting the luminance to match that of pixels disposed in a general area as the distance from the optical area increases.

According to embodiments of the present disclosure, a display device and a timing controller may solve the problem of reduced lifespan of a specific pixel caused by concentration of high luminance operation on the specific pixel by sequentially changing pixels in a unit pixel disposed in the boundary area based on a certain point in time.

According to embodiments of the present disclosure, a display device and a timing controller may prevent visibility of a boundary line with low power consumption by sequentially driving pixels that emit light in a high luminance state among the pixels disposed in the boundary area, thereby extending the lifespan of each pixel.

Although certain embodiments and implementations have been described herein, other embodiments and modifications will be apparent from this description. Accordingly, the inventive concepts are not limited to such embodiments, but rather to the broader scope of the appended claims and various obvious modifications and equivalent arrangements as would be apparent to a person of ordinary skill in the art.

What is claimed is:

1. A display device comprising:
a display panel including a general area, an optical area configured to transmit light, and a boundary area disposed between the general area and the optical area;
a unit pixel including at least two pixels disposed in the boundary area, the at least two pixels being configured to emit light by receiving a gate signal through a gate driving circuit in the display panel; and
a timing controller configured to control the gate driving circuit,
wherein at least some of the at least two pixels included in the unit pixel emit light in a high luminance state, and the remaining pixels emit light in a low luminance state, and
wherein the high luminance state or the low luminance state of the at least two pixels sequentially changes within the unit pixel according to a value of a counting signal of the timing controller.

2. The display device according to claim 1,
wherein, in case that power is applied to the display panel, a start signal is supplied from the timing controller, and
wherein a value of the counting signal is incremented each time the start signal is supplied to the timing controller.

3. The display device according to claim 1,
wherein the gate driving circuit receives a gate start signal from the timing controller for each frame of an image displayed on the display panel, and
wherein the counting signal corresponds to a value that is incremented each time the gate start signal is supplied to the gate driving circuit.

4. The display device according to claim 1, wherein, among the at least two pixels included in the unit pixel, one pixel is configured to emit light in the high luminance state, and the remaining pixels, other than the pixel that emits light in the high luminance state, emit light in the low luminance state.

5. The display device according to claim 1,
wherein the unit pixel comprises N pixels, N being a natural number equal to or greater than 2,
wherein a value of the counting signal is sequentially incremented from a value indicating a first state to a value indicating an N-th state under control of the timing controller, and after the value indicates the N-th state, the value is again incremented starting from the value indicating the first state,
wherein, in case that the counting signal has a value indicating the first state, a first pixel in the unit pixel emits light in the high luminance state, and the remaining pixels emit light in the low luminance state, and
wherein, in case that the counting signal has a value indicating the N-th state, an N-th pixel in the unit pixel emits light in the high luminance state, and the remaining pixels emit light in the low luminance state.

6. The display device according to claim 1, wherein the value of the counting signal is stored in a memory of the timing controller.

7. The display device according to claim 1,
wherein, in the boundary area, luminance of the pixels that emit light in the high luminance state gradually decreases as a distance from the optical area increases, and
wherein luminance of the pixels that emit light in the low luminance state gradually increases as the distance from the optical area increases.

8. The display device according to claim 1,
wherein the optical area includes a transmissive area that is configured to transmit light,
wherein the transmissive area and the pixels are not vertically overlapped in the display panel, and
wherein the number of pixels per unit area in the optical area is less than in the general area and the boundary area.

9. The display device according to claim 8,
wherein an optical electronic device is disposed in the optical area, and
wherein the optical electronic device is configured to perform a predefined operation using light transmitted through the transmissive area.

10. The display device according to claim 1, wherein the display panel is disposed in a front cluster of an interior of a vehicle.

11. A timing controller configured to control a plurality of pixels disposed in a display panel, the pixels being configured to emit light by receiving gate signals through a gate driving circuit,
wherein the timing controller is configured to control a unit pixel including at least two pixels disposed in the display panel,
wherein at least some of the at least two pixels included in the unit pixel are configured to emit light in a high luminance state, and the remaining pixels are configured to emit light in a low luminance state, and
wherein the high luminance state or the low luminance state of the at least two pixels sequentially changes within the unit pixel according to a value of a counting signal of the timing controller.

12. The timing controller according to claim 11,
wherein, in case that power is applied to the display panel, a start signal is supplied to the timing controller, and
wherein a value of the counting signal is incremented each time the start signal is supplied to the timing controller.

13. The timing controller according to claim 11,
wherein the gate driving circuit is configured to receive a gate start signal from the timing controller for each frame of an image displayed on the display panel, and
wherein a value of the counting signal is incremented each time the gate start signal is supplied to the gate driving circuit.

14. The timing controller according to claim 11,
wherein the unit pixel includes N pixels, N being a natural number equal to or greater than 2,
wherein a value of the counting signal is sequentially incremented from a value indicating a first state to a value indicating an N-th state under control of the timing controller, and after the value indicates the N-th state, the value is again incremented starting from the value indicating the first state,
wherein, in case that the counting signal has a value indicating the first state, a first pixel in the unit pixel emits light in the high luminance state, and the remaining pixels emit light in the low luminance state, and
wherein, in case that the counting signal has a value indicating the N-th state, an N-th pixel in the unit pixel emits light in the high luminance state, and the remaining pixels emit light in the low luminance state.

15. The timing controller according to claim 11, further comprising a memory in which the value of the counting signal is stored.

16. The timing controller according to claim 11,
wherein the luminance of pixels that emit light in the high luminance state at a first point of the display panel gradually decreases as a distance from the first point increases, and
wherein the luminance of pixels that emit light in the low luminance state at the first point gradually increases as a distance from the first point increases.

17. A method of driving a display device including a display panel, the method comprising:
supplying power to the display device;
supplying power to a timing controller and generating, by the timing controller, a start signal;
accumulating the generated start signal in a memory disposed in the timing controller;
initializing a gate driving circuit by supplying an initialization signal from the timing controller to the gate driving circuit;
displaying a black screen on the display panel after initialization of the gate driving circuit;
repeatedly performing a blank stage and a display driving stage while the display device remains powered on;
displaying an image on the display panel after the blank stage ends;
determining whether a power-off signal is applied from the display device; and
in response to determining that the power‑off signal is applied, turning off power and stop driving the display device.

18. The method of claim 17, wherein the accumulating of the generated start signal includes incrementing a counting value stored in the memory each time the timing controller generates the start signal.

19. The method of claim 17, wherein the initializing of the gate driving circuit includes discharging nodes of the gate driving circuit to an initial voltage level or setting the nodes to a predetermined reference voltage.

20. The method of claim 17, wherein the displaying of the black screen includes supplying, by a data driving circuit, data voltages that minimize light emission of all sub‑pixels included in the display panel.
